(19) United States
(12) Patent Application Publication
(10) Pub. No.: US 2016/0260643 A1
(43) Pub. Date: Sep. 8, 2016

(54) SEMICONDUCTOR DEVICE AND MANUFACTURING METHOD OF SEMICONDUCTOR DEVICE

(71) Applicant: Kabushiki Kaisha Toshiba, Minato-ku (JP)

(72) Inventor: Takeshi KOSHIBA, Yokkaichi (JP)

(73) Assignee: Kabushiki Kaisha Toshiba, Minato-ku (JP)

(21) Appl. No.: 14/847,517

(22) Filed: Sep. 8, 2015

Related U.S. Application Data
(60) Provisional application No. 62/129,508, filed on Mar. 6, 2015.

(51) Int. Cl. H01L 21/66; H01L 21/3065; H01L 21/308; H01L 23/544

(52) U.S. Cl. CPC H01L 22/20; H01L 23/544; H01L 21/3065; H01L 21/3085; H01L 22/12; H01L 2223/5446

(57) ABSTRACT

According to one embodiment, there is provided a semiconductor device having a mark, the mark including a reference pattern extending in a first direction, a measuring pattern extending in the first direction, and a first stepped portion. The measuring pattern is separated by a predetermined distance in the second direction intersecting the first direction from the reference pattern. The first stepped portion has a level difference of one or more steps and is disposed on side in the second direction of the measuring pattern.

### CROSS-REFERENCE TO RELATED APPLICATIONS

This application is based upon and claims the benefit of priority from U.S. Provisional Application No. 62/129,508, filed on Mar. 6, 2015; the entire contents of which are incorporated herein by reference.

### FIELD

Embodiments described herein relate generally to a semiconductor device and a method of manufacturing a semiconductor device.

### BACKGROUND

In a method of manufacturing a semiconductor device, a technique of forming a resist pattern on a film to be processed and then repeatedly performing a slimming process of reducing the size of the resist pattern through anisotropic etching and isotropic etching of the film using the resist pattern as a mask is known.

However, a technique of simply and accurately measuring a reduced size (hereinafter, referred to as a slimming amount) of the resist pattern due to one slimming process has not been proposed in the related art.

### BRIEF DESCRIPTION OF THE DRAWINGS

FIG. 1 is a top view schematically illustrating an example of a semiconductor device according to a first embodiment;

FIG. 2 is a perspective view schematically illustrating an example of a structure of a nonvolatile semiconductor memory device;

FIGS. 3A and 3B are diagrams illustrating an example of a configuration of a slimming amount monitoring mark according to the first embodiment;

FIGS. 4A and 4B are diagrams illustrating an example of a method of measuring a slimming amount monitoring mark;

FIG. 5 is a diagram schematically illustrating an example of a configuration of an apparatus for manufacturing a semiconductor device according to the first embodiment;

FIGS. 6A to 8C are diagrams schematically illustrating an example of a method of manufacturing a semiconductor device according to the first embodiment;

FIG. 9 is a flowchart illustrating an example of a process flow of the method of manufacturing a semiconductor device according to the first embodiment;

FIGS. 10A and 10B are top views illustrating examples of an arrangement state of slimming amount monitoring marks;

FIG. 11 is a diagram illustrating an example of a method of measuring the slimming amount monitoring marks illustrated in FIG. 10A;

FIGS. 12A and 12B are cross-sectional views schematically illustrating another example of the slimming amount monitoring marks;

FIG. 13 is a flowchart illustrating an example of a process flow of the method of manufacturing a semiconductor device according to a second embodiment; and

FIG. 14 is a diagram illustrating an example of a hardware configuration of a control device.

### DETAILED DESCRIPTION

According to one embodiment, there is provided a semiconductor device having a mark which includes a reference pattern extending in a first direction, a measuring pattern extending in the first direction, and a first stepped portion. The measuring pattern is separated by a predetermined distance from the reference pattern in a second direction intersecting the first direction. The first stepped portion has a level difference of one or more steps and is disposed on one side in the second direction of the measuring pattern.

Hereinafter, a semiconductor device and a method of manufacturing a semiconductor device according to the exemplary embodiments will be described in detail with reference to the accompanying drawings. The present invention is not limited to the exemplary embodiments. The cross-sectional views, the top views, and the perspective views of a semiconductor device which are used in the following embodiments are schematic, and a relation between thickness and width of a layer, ratios of thicknesses of respective layers, and the like may be different from actual ones.

### First Embodiment

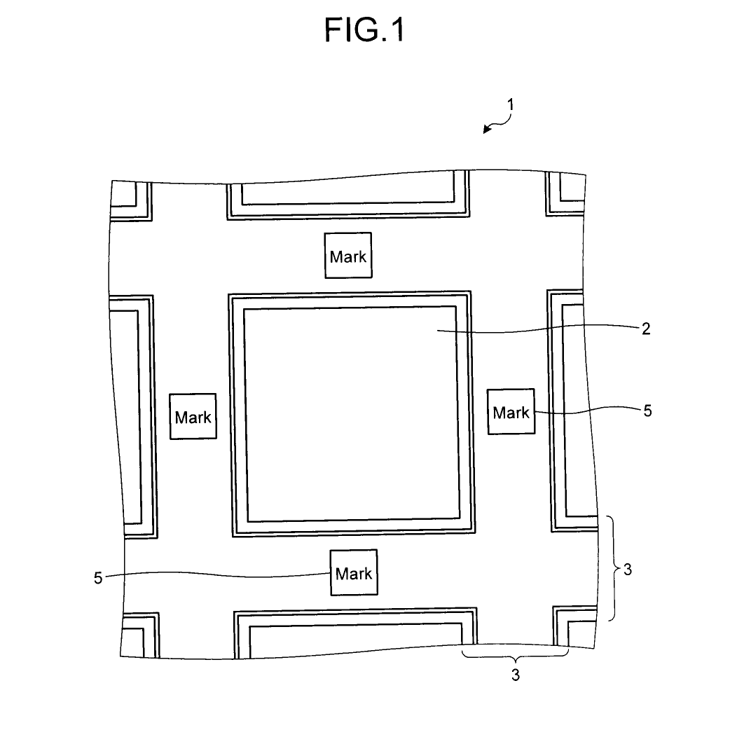

FIG. 1 is a top view schematically illustrating an example of a semiconductor device according to a first embodiment. The drawing illustrates a state before a wafer is cut into semiconductor chips. As illustrated in FIG. 1, plural semiconductor chips 2 are formed on a substrate (wafer) 1. An example of the semiconductor chip 2 is a memory chip including NAND type flash memory in which memory cells are three-dimensionally arranged.

A scribe line 3 is disposed between the semiconductor chips 2. A mark area is disposed on the scribe line 3 and a mark 5 is disposed in the mark area. The mark 5 includes a slimming amount monitoring mark which will be described in this embodiment, in addition to a positioning mark in a lithography process. The mark 5 is formed with formation of the semiconductor chip 2.

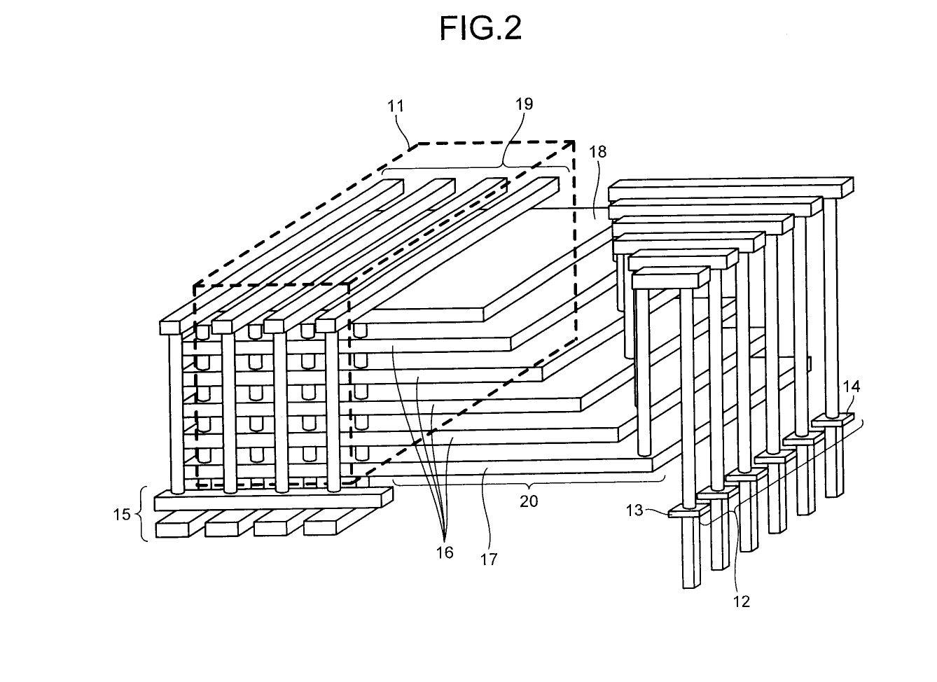

FIG. 2 is a perspective view schematically illustrating an example of a structure of a nonvolatile semiconductor memory device. The nonvolatile semiconductor memory device includes a memory cell section 11, a word line driving circuit 12, a source-side selection gate line driving circuit 13, a drain-side selection gate line driving circuit 14, a sense amplifier 15, a word line 16, a source-side selection gate line 17, a drain-side selection gate line 18, and a bit line 19.

The memory cell section 11 has a configuration in which memory strings including plural memory cell transistors (hereinafter, simply referred to as memory cells) and a drain-side selection transistor and a source-side selection transistor disposed on the top and bottom of each memory cell transistor string are arranged in a matrix shape above the substrate. Each memory cell transistor has, for example, a structure in which a control gate electrode is disposed on a side surface of a columnar semiconductor film serving as a channel with a charge storage layer interposed therebetween. The drain-side selection transistor and the source-side selection transistor have a structure in which a selection gate electrode is disposed on a side surface of a columnar semiconductor film with a charge storage layer as a gate dielectric film interposed therebetween. Here, it is assumed that four layers of memory cells are disposed in one memory string.

The word line 16 connects the control gate electrodes of the memory cells located at the same height in the memory strings adjacent to each other in a predetermined direction. The direction in which the word line 16 extends is hereinafter referred to as a word line direction. The source-side selection gate line 17 connects the selection gate electrodes of the source-side selection transistors of the memory strings adjacent to each other in the word line direction. The drain-side selection gate line 18 connects the selection gate electrodes of the drain-side selection transistors of the memory strings adjacent to each other in the word line direction. The bit line 19 is formed to be connected to the tops of the memory strings in a direction (herein, perpendicular direction) intersecting the word line direction.

The word line driving circuit 12 is a circuit configured to control a voltage to be applied to the word line 16, the source-side selection gate line driving circuit 13 is a circuit configured to control a voltage to be applied to the source-side selection gate line 17, and the drain-side selection gate line driving circuit 14 is a circuit configured to control a voltage to be applied to the drain-side selection gate line 18. The sense amplifier 15 is a circuit configured to amplify a potential read from the selected memory cell. In the following description, the source-side selection gate line 17 and the drain-side selection gate line 18 are simply referred to as selection gate lines when both do not need to be distinguished from each other. The source-side selection transistor and the drain-side selection transistor are simply referred to as selection transistors when both do not need to be distinguished from each other.

The word line 16, the source-side selection gate line 17, and the drain-side selection gate line 18 of the memory cell section 11 are connected to the word line driving circuit 12, the source-side selection gate line driving circuit 13, and the drain-side selection gate line driving circuit 14 respectively via contacts in a word line contact portion 20 formed in the memory cell section 11. The word line contact portion 20 is formed on the word line driving circuit 12 side of the memory cell section 11 and has a structure in which the word line 16 and the selection gate lines 17 and 18 connected to the memory cells and the selection transistors at the respective heights are formed in a step shape.

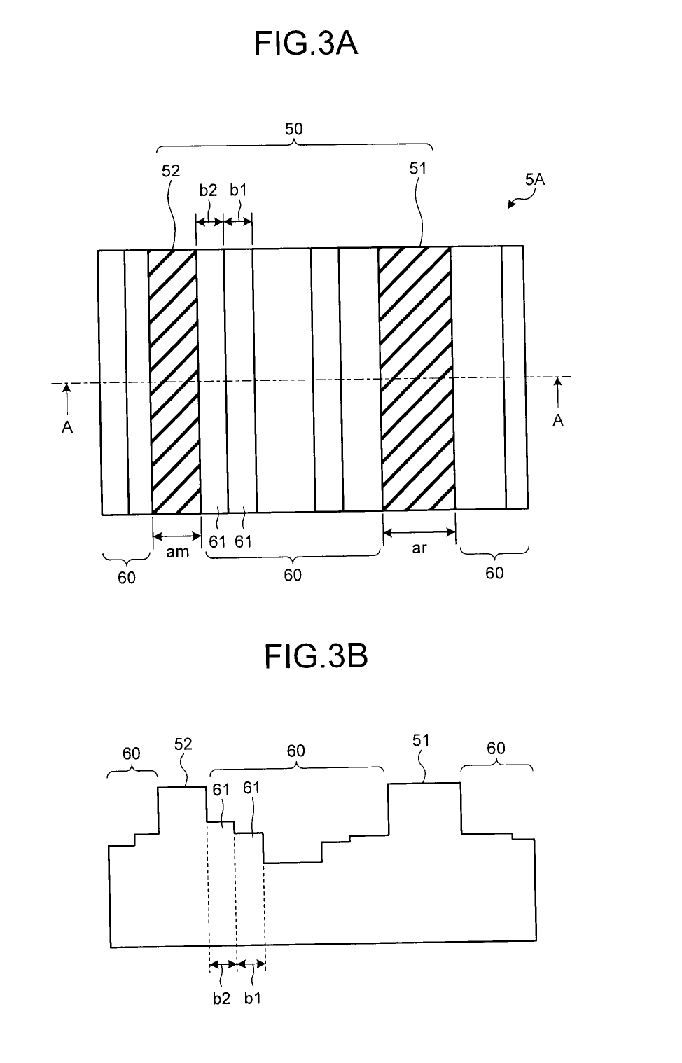

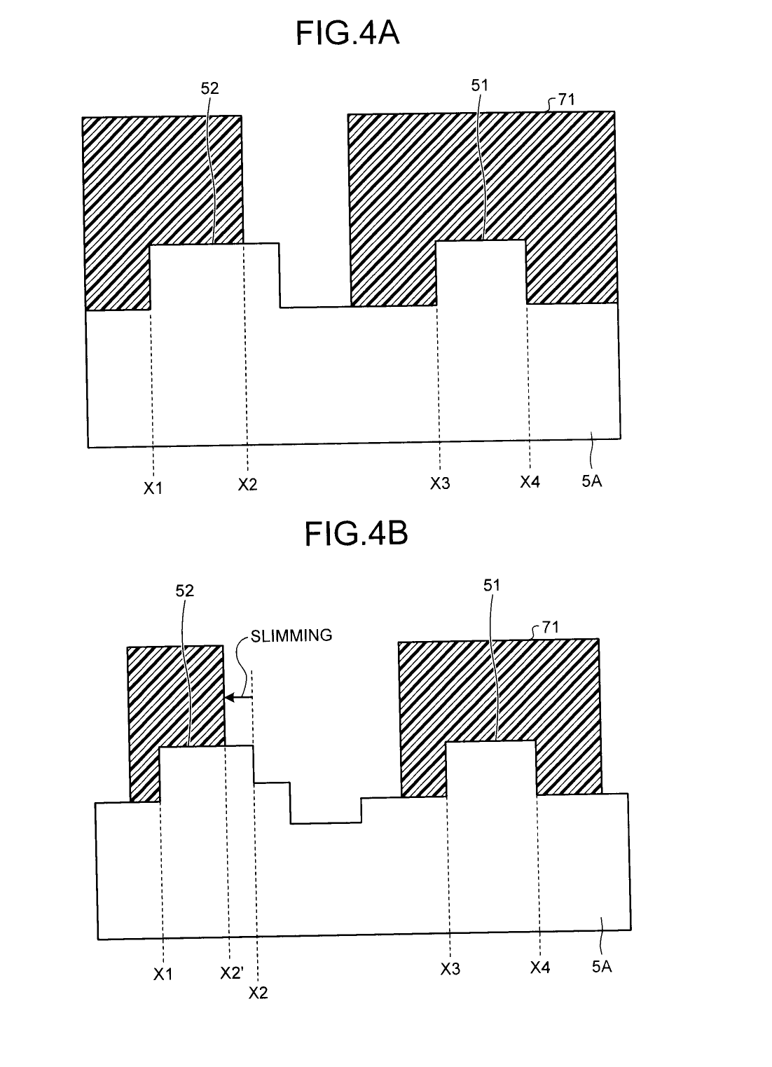

FIGS. 3A and 3B are diagrams illustrating an example of a configuration of a slimming amount monitoring mark according to the first embodiment, where FIG. 3A is a top view of the slimming amount monitoring mark and FIG. 3B is a cross-sectional view taken along line A-A of FIG. 3A. Although FIG. 3A is a top view, a line pattern 50 is hatched to be easily distinguished from a step pattern 60. The slimming amount monitoring mark 5A includes a pair of line patterns 50 and step patterns 60 formed around the line patterns 50.

The pair of line patterns 50 includes a reference pattern 51 and a measuring pattern 52. The reference pattern 51 is a pattern serving as a reference when measuring a slimming amount of a resist pattern. The reference pattern 51 is not processed by etching when monitoring a slimming amount as will be described later. The measuring pattern 52 is a pattern used to calculate a slimming amount of a resist pattern. The measuring pattern 52 is processed by etching when monitoring the slimming amount as will be described later. Accordingly, the width am of the measuring pattern 52 after the etching is less than that when forming the slimming amount monitoring mark 5A.

The step pattern 60 is formed on both sides in a direction intersecting the extending direction of the reference pattern 51 and the measuring pattern 52. In general, a level difference corresponding to the number of steps formed is generated. FIGS. 3A and 3B illustrate an example in which the step pattern corresponding to two steps is formed. The level difference which is used to measure the slimming amount is a level difference on the side, in which the resist pattern is not formed through the etching, of the measuring pattern 52. In this example, steps 61 on the reference pattern 51 side of the measuring pattern 52 are used to measure the slimming amount.

A direction perpendicular to the step-forming direction in the stepped structure is the extending direction of the reference pattern 51 and the measuring pattern 52. Accordingly, for example, when the measuring of the slimming amount of the resist pattern in forming steps in the word line contact portion 20 in FIG. 2 is intended, the slimming amount monitoring mark 5A is formed such that the extending direction of the reference pattern 51 and the measuring pattern 52 is perpendicular to the step-forming direction in the word line contact portion 20.

The widths of the reference pattern 51 and the measuring pattern 52 before the etching process is performed are appropriately set depending on the number of steps at which the slimming amount is measured. For example, in the word line contact portion 20 of the nonvolatile semiconductor memory device illustrated in FIG. 2, the length of a flat portion per step in the stepped structure has a size of about 500 nm to 1 μm. Accordingly, the lengths of the reference pattern 51 and the measuring pattern 52 are set depending on the number of steps to be measured. The length of the flat portion which is mentioned herein is a size in the step-forming direction. For example, when the measuring of the slimming amount corresponding to four steps with a length of about 500 nm is intended, the width ar of the reference pattern 51 and the width am of the measuring pattern 52 are equal to or greater than 2.5 μm. The width of the reference pattern 51 and the width of the measuring pattern 52 in forming the slimming amount monitoring mark 5A may not be equal to each other.

Now, a method of measuring the slimming amount monitoring mark 5A will be described. FIGS. 4A and 4B are diagrams illustrating an example of the method of measuring the slimming amount monitoring mark. FIG. 4A illustrates a state in which a step-forming resist pattern is formed on a slimming amount monitoring mark. FIG. 4B illustrates a state in which the resist pattern is slimmed to form a next step after an etching process is performed in FIG. 4A.

As illustrated in FIG. 4A, the entire reference pattern 51 is covered with the resist pattern 71 and only a predetermined region of the measuring pattern 52 including one long side (edge) is covered with the resist pattern 71. It is assumed that the position of the edge of the measuring pattern 52 covered with the resist pattern 71 is defined as X1, the position of the end of the resist pattern on the measuring pattern 52 is defined as X2, the position of the edge of the reference pattern 51 facing the measuring pattern 52 is defined as X3, and the position of the edge of the reference pattern 51 not facing the measuring pattern 52 is defined as X4. The positions X1 to X4 are measured using an optical displacement inspection device and a reference pattern width Wr is calculated by Expression (1). X1X4 denotes a distance between the position X1 and the position X4, and X2X3 denotes a distance between the position X2 and the position X3.

Wr=X1X4−X2X3

When the resist pattern 71 is slimmed after the etching process is performed in FIG. 4A, the state illustrated in FIG. 4B is obtained. At this time, the position of the end of the resist pattern 71 on the measuring pattern 52 is present at a position X2′ different from that in the state illustrated in FIG. 4A. In this state, similarly to the state illustrated in FIG. 4A, the pattern width Wm after the etching process is performed is calculated by Expression (2). X2′X3 denotes a distance between the position X2′ and the position X3.

Wm=X1X4−X2′X3

A recession amount, that is, a slimming amount AW, of the resist pattern 71 is calculated by Expression (3) using the reference pattern width Wr and the pattern width Wm after the etching.

ΔW=Wm−Wr

In another example, a first inter-center distance between the reference pattern 51 and the measuring pattern 52 in a non-processed state and a second inter-center distance between the reference pattern 51 and the measuring pattern 52 in a processed state may be measured using the optical displacement inspection device and a size variation due to the slimming of the resist pattern 71 may be calculated depending on the variation in the first inter-center distance and the second inter-center distance.

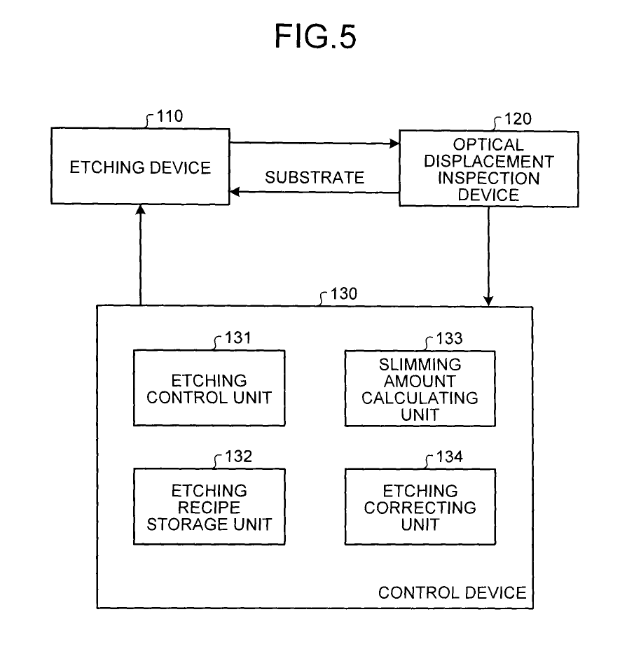

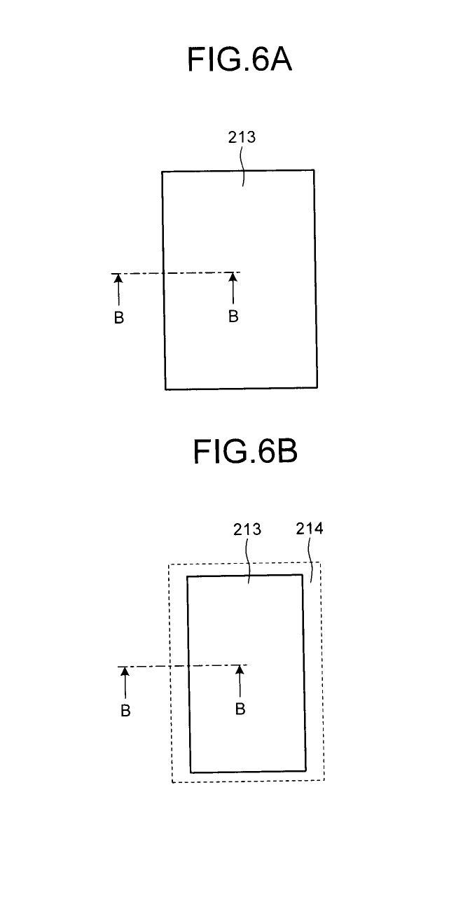

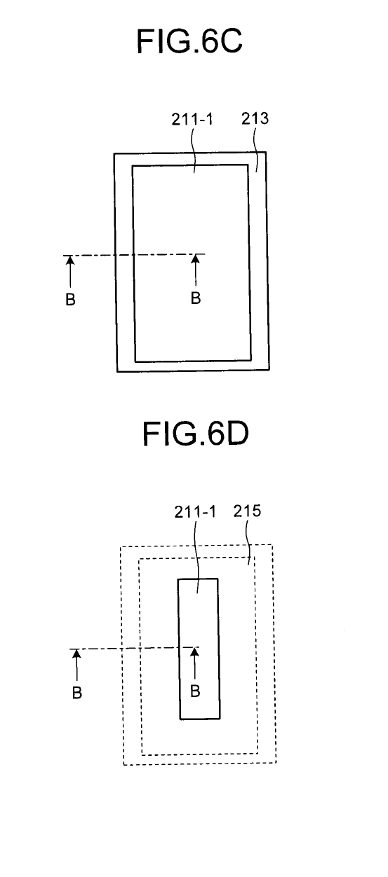

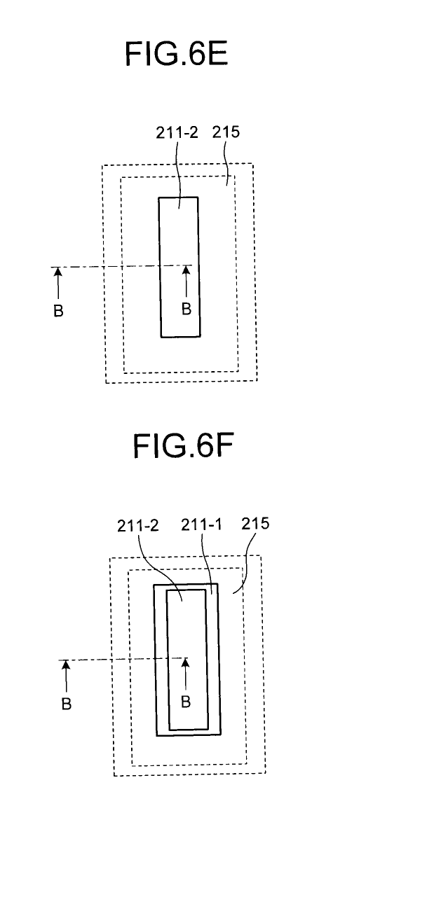

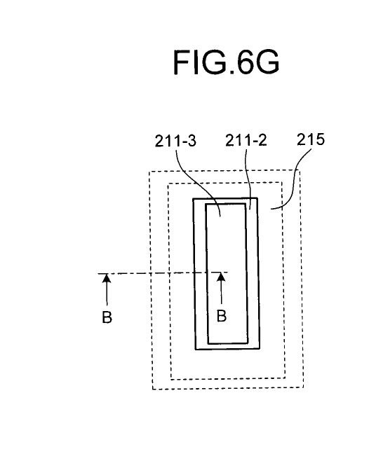

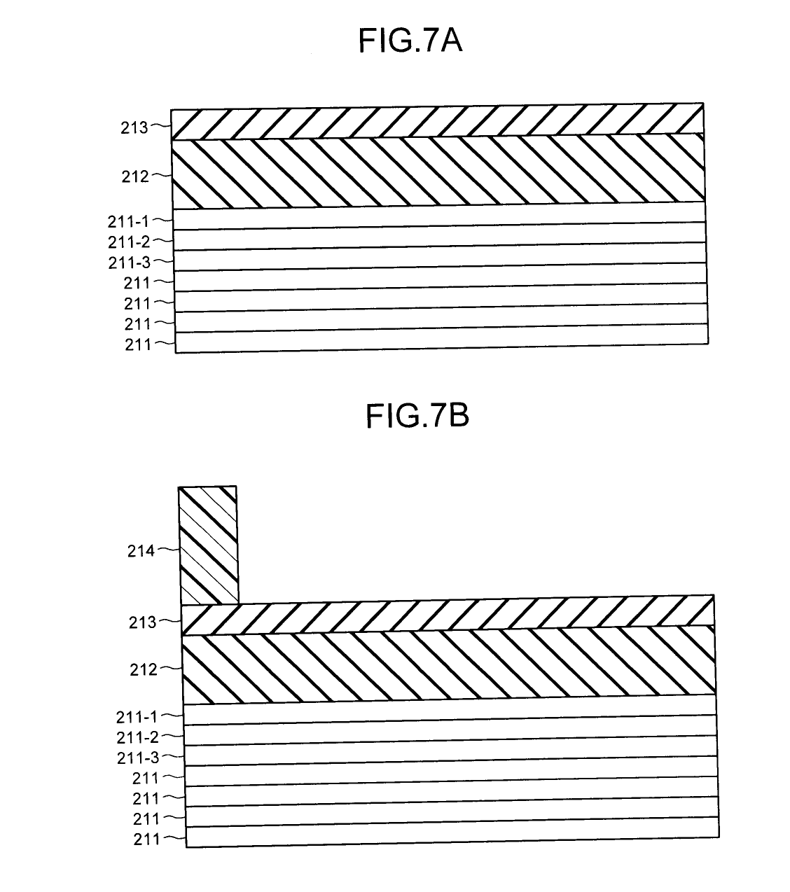

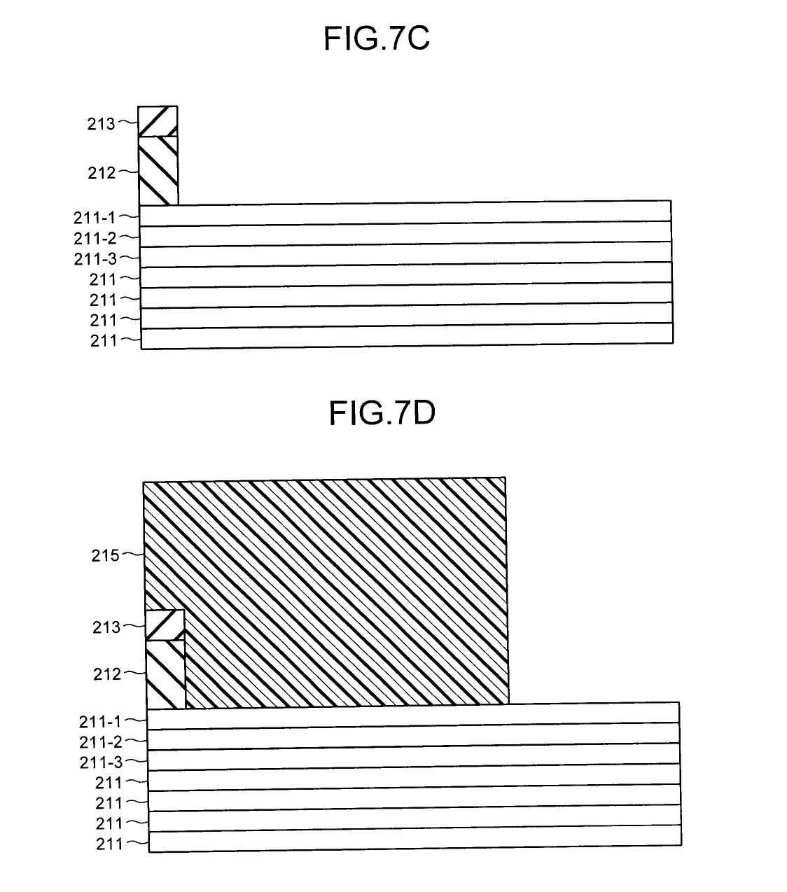

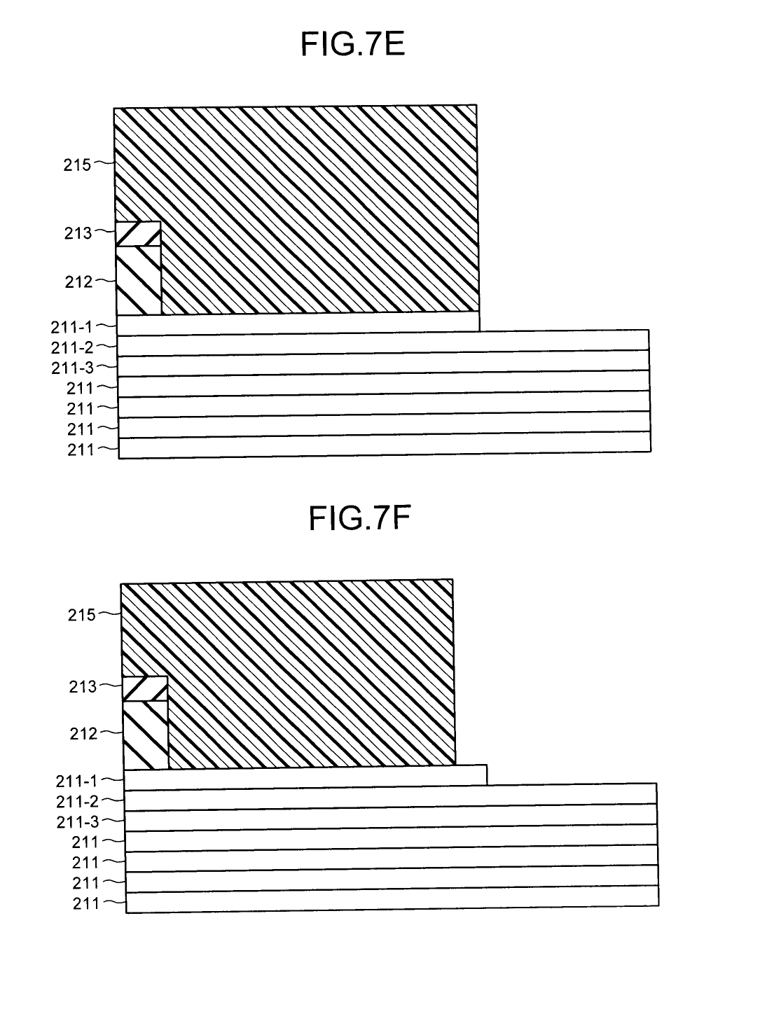

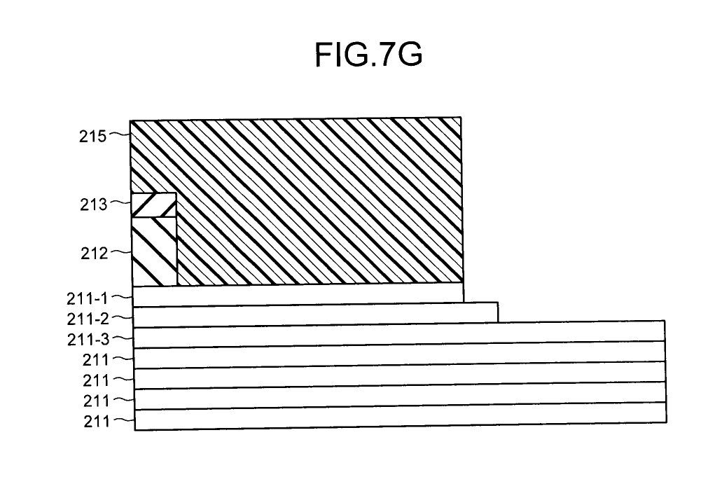

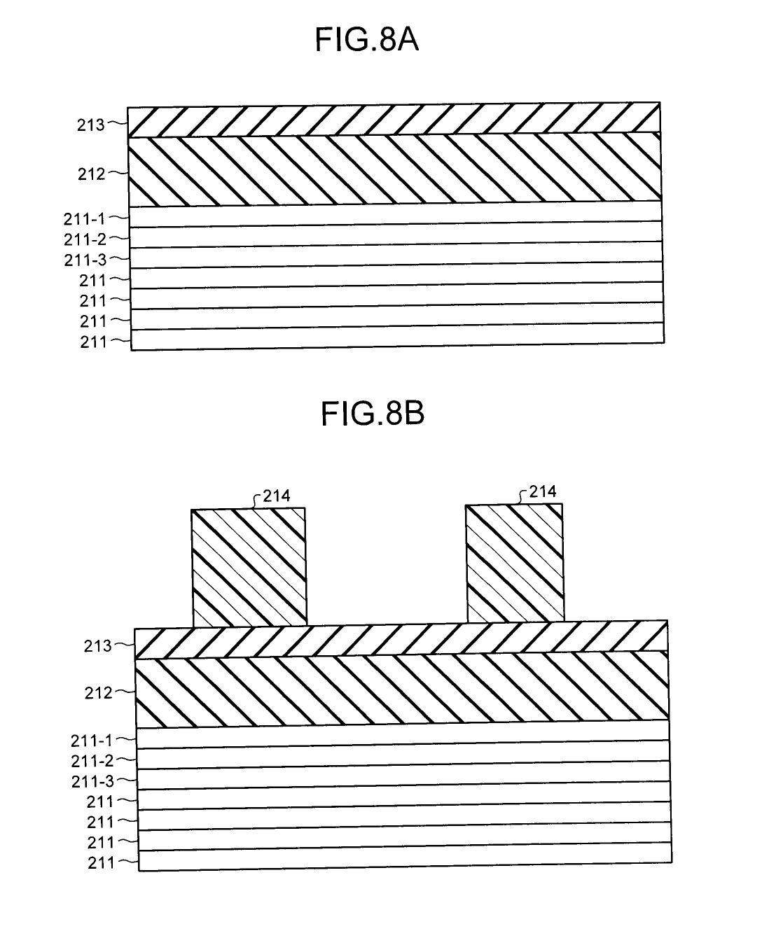

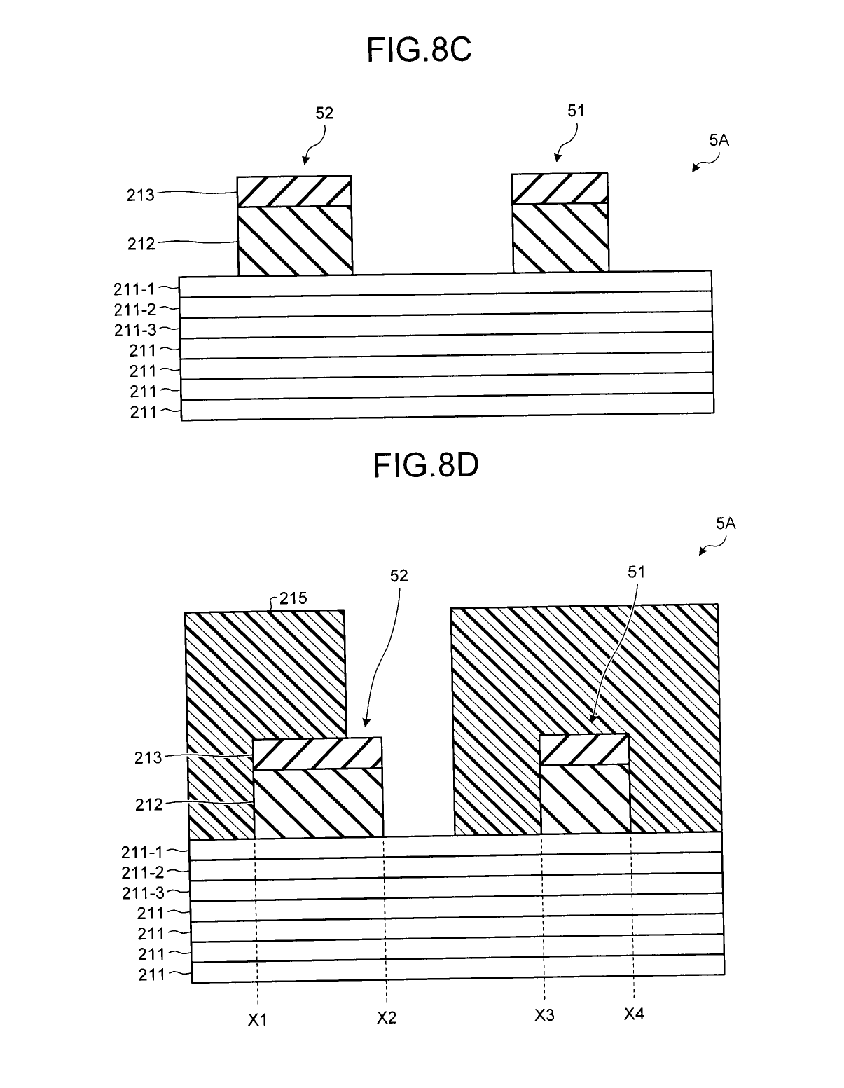

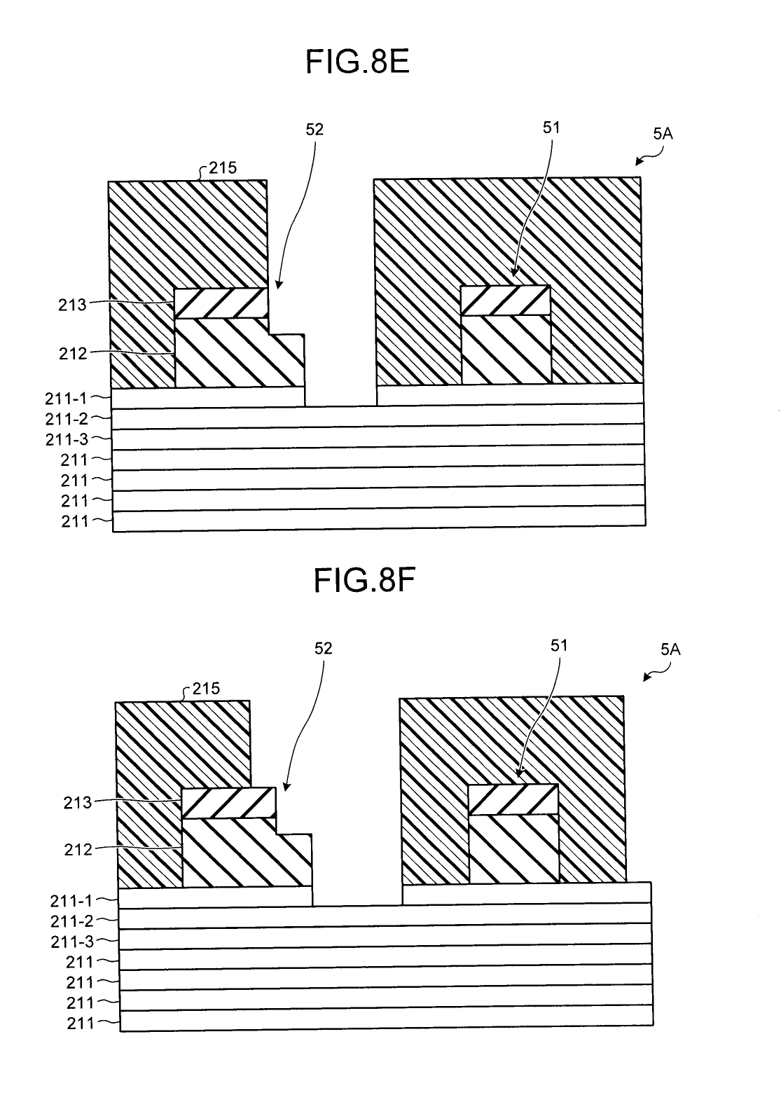

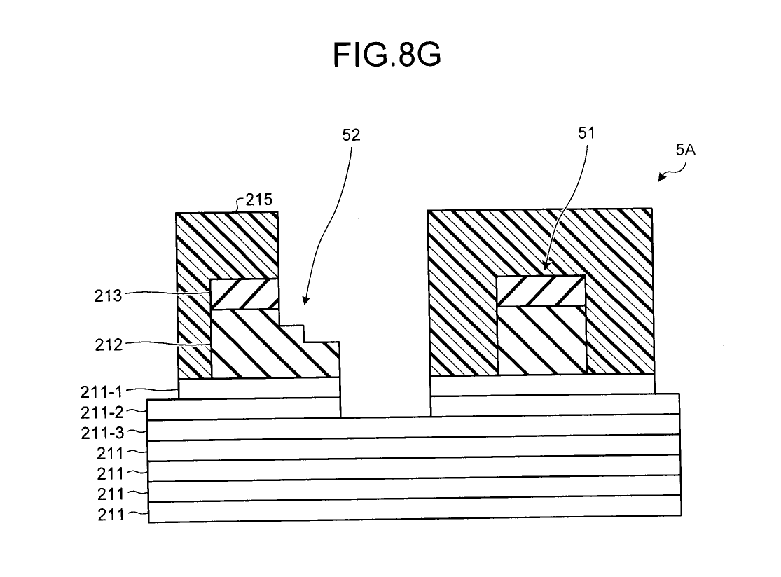

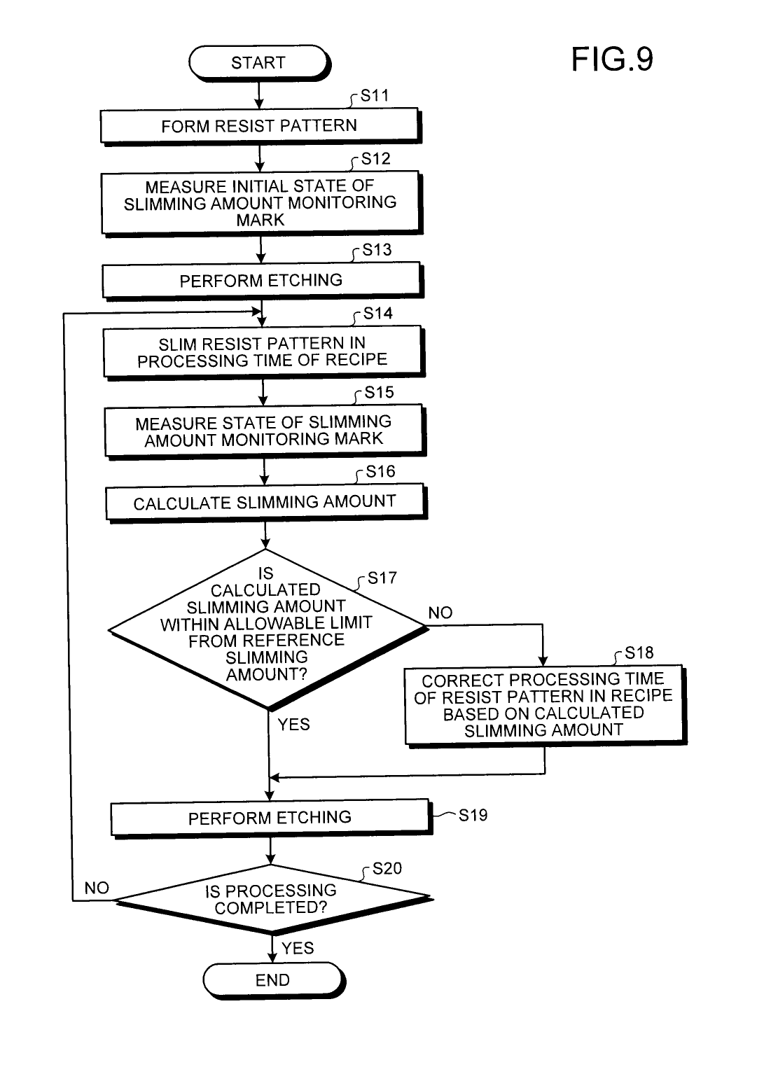

A method of manufacturing a semiconductor device using the slimming amount monitoring mark 5A will be described below. Here, a method of forming a word line contact portion having a stepped structure in a nonvolatile semiconductor memory device having a three-dimensional structure will be described. FIG. 5 is a diagram schematically illustrating an example of a configuration of an apparatus for manufacturing the semiconductor device according to the first embodiment. FIGS. 6A to 8G are diagrams schematically illustrating an example of the method of manufacturing a semiconductor device according to the first embodiment, where FIGS. 6A to 6G are top views of the word line contact portion, FIGS. 7A to 7G are cross-sectional views taken along line B-B of FIGS. 6A to 6G, and FIGS. 8A to 8G are cross-sectional views of the slimming amount monitoring mark. FIG. 9 is a flowchart illustrating an example of a process flow of the method of manufacturing a semiconductor device according to the first embodiment.

As illustrated in FIG. 5, an etching device 110, an optical displacement inspection device 120, and a control device 130 are used to manufacture a semiconductor device according to this embodiment. The etching device 110 is, for example, a reactive ion etching (RIE) device. The RIE device is a device configured to apply a radio-frequency voltage to a substrate holder to generate plasma and to etch the substrate which supplying gas between the substrate holder holding a substrate and an upper electrode. The optical displacement inspection device 120 is a device configured to measure the positions of the reference pattern 51 and the measuring pattern 52 illustrated in FIGS. 4A and 4B using light of a visible light region.

The control device 130 controls the processing of the etching device 110 based on an etching recipe. The control device 130 includes an etching control unit 131, an etching recipe storage unit 132, a slimming amount calculating unit 133, and an etching correcting unit 134. The etching control unit 131 controls processes of feeding a substrate as a processing target to the substrate holder in the etching device 110, adjusting the pressure and the gas atmosphere in the etching device 110, generating plasma, and etching the substrate based on the etching recipe.

The etching recipe storage unit 132 stores the etching recipe including processing conditions and orders in the etching device 110. The etching recipe is prepared in advance, for example, by an operator for manufacturing a semiconductor device. In the etching recipe, a slimming time of a resist pattern is also defined in addition to an etching time. The slimming time is a time required for etching the resist pattern by a predetermined amount in a direction parallel to the substrate surface. The etching recipe storage unit 132 is constituted by a nonvolatile memory device such as a hard disk drive (HDD) or a solid state drive (SSD).

The slimming amount calculating unit 133 calculates the slimming amount from the measurement result of the optical displacement inspection device 120. The slimming amount is calculated by the slimming amount calculating unit 133 using Expressions (1) to (3).

The etching correcting unit 134 determines whether the calculated slimming amount calculated by the slimming amount calculating unit 133 is within an allowable limit from a slimming amount (hereinafter referred to as a reference slimming amount) defined in the etching recipe storage unit 132. When the calculated slimming amount is within the allowable limit from the reference slimming amount, the etching recipe is not corrected. When the calculated slimming amount is not within the allowable limit from the reference slimming amount, the slimming time of the etching recipe is corrected. Specifically, a difference between the calculated slimming amount and the reference slimming amount is calculated and the slimming time is corrected to compensate for the difference. This correction can be performed using a calibration curve which is acquired in advance and which denotes a relationship between the slimming amount and the slimming time in the etching device 100.

The etching control unit 131, the slimming amount calculating unit 133, and the etching correcting unit 134 constituting the control device 130 are realized by software.

The semiconductor device manufacturing method including the measuring of the slimming amount will be described below. First, as illustrated in FIGS. 6A, 7A, and 8A, plural pair layers 211 in which different types of films are stacked are stacked on a substrate not illustrated. Examples of the pair layer 211 include a combination of a silicon oxide film and a silicon nitride film and a combination of a silicon oxide film and an amorphous silicon film. By stacking the pair layers 211, different types of films are alternately stacked. In the drawings, the pair layer 211 is illustrated as a single layer. In the drawings, the uppermost pair layer of the pair layers 211 is referenced by reference numeral 211-1 and the second uppermost pair layer and the third uppermost pair layer are referenced by reference numerals 211-2 and 211-3. In addition, an insulating film 212 such as a silicon oxide film is formed on the plural pair layers 211 and an insulating film 213 such as a silicon nitride film is formed thereon.

Subsequently, as illustrated in FIGS. 6B, 7B, and 8B, a resist is applied onto the insulating film 213 and a resist pattern 214 in which a forming area of the word line contact portion 20 is opened is formed using a lithography technique and a developing technique. At a forming position of a slimming amount monitoring mark 5A on a scribe line, the resist pattern 214 is formed to form a pair of line patterns 50.

Thereafter, as illustrated in FIGS. 6C, 7C, and 8C, anisotropic etching such as an RIE process is performed by the etching device 110 using the resist pattern 214 as a mask to remove the insulating films 213 and 212. Accordingly, an area in which a stepped contact portion is formed is formed in the forming area of the word line contact portion 20. In the forming area of the word line contact portion 20, a part of the pair layer 211-1 is exposed. The slimming amount monitoring mark 5A having the reference pattern 51 and the measuring pattern 52 is formed on the scribe line. The pair layer 211-1 is exposed in the area between the reference pattern 51 and the measuring pattern 52.

Subsequently, as illustrated in FIGS. 6D, 7D, and 8D, a resist is applied onto the insulating film 213 and the pair layers 211 and a resist pattern 215 having a predetermined shape is formed using a lithography technique and a developing technique (step S11). The resist pattern 215 in which the vicinity of the center of the forming area of the word line contact portion 20 is opened is formed in the forming area of the word line contact portion 20. On the scribe line, the resist pattern 215 with which the entire reference pattern 51 is covered, one edge of the measuring pattern 52 is covered, and the other edge is not covered is formed. The width of the resist pattern 215 covering the reference pattern 51 is determined so as not to expose the reference pattern 51 even when the resist pattern 215 is slimmed the number of times in which the measuring of the slimming amount is intended.

Thereafter, the substrate on which the resist pattern 215 is formed is fed to the optical displacement inspection device 120 and the initial state of the slimming amount monitoring mark 5A is measured therein (step S12). Since the resist pattern 215 transmits light with wavelengths of a visible light region, the slimming amount monitoring mark 5A can be measured even in a state in which the slimming amount monitoring mark 5A is covered with the resist pattern 215. The optical displacement inspection device 120 sends the measurement result to the control device 130.

Subsequently, the substrate is fed to the etching device 110 and an etching process is performed using the resist pattern 215 as a mask as illustrated in FIGS. 6E, 7E, and 8E (step S13). Here, the control device 130 performs control such that the etching process is performed in only the time in which the pair layer 211-1 is etched in the area in which the pair layers 211 are exposed based on the etching recipe. Accordingly, the pair layer 211-2 is exposed in the forming area of the word line contact portion 20. At the forming position of the slimming amount monitoring mark 5A, the pair layer 211-1 of the area between the reference pattern 51 and the measuring pattern 52 is removed and the pair layer 211-2 is exposed. The insulating films 213 and 212 in the area in which the measuring pattern 52 is exposed are etched to form a step.

Thereafter, as illustrated in FIGS. 6F, 7F, and 8F, the control device 130 controls the etching device 110 so as to isotropically etch the resist pattern 215 depending on the processing time of the etching recipe (step S14).

Subsequently, the substrate subjected to the slimming is fed to the optical displacement inspection device 120 and the state of the slimming amount monitoring mark 5A is measured (step S15). The optical displacement inspection device 120 sends the measurement result to the control device 130.

Subsequently, the control device 130 calculates a slimming amount using the inspection result from the optical displacement inspection device 120 which is obtained in steps S12 and S15 (step S16). Thereafter, it is determined whether the calculated slimming amount is within a predetermined range (allowable limit) from the reference slimming amount of the etching recipe (step S17). The reference slimming amount is a target etching amount.

When the calculated slimming amount is not within the allowable limit from the reference slimming amount (NO in step S17), the processing time of the resist pattern in the etching recipe is corrected depending on the calculated slimming amount (step S18). For example, when the calculated slimming amount is less than the allowable limit from the reference slimming amount, the slimming amount is not sufficient. Therefore, a time in which an amount corresponding to the difference between the calculated slimming amount and the reference slimming amount can be etched is calculated. By adding the calculated time to the processing time in the etching recipe, the processing time is corrected. On the contrary, when the calculated slimming amount is greater than the allowable limit from the reference slimming amount, the slimming amount is excessive. Therefore, a time in which an amount corresponding to the difference between the reference slimming amount and the calculated slimming amount is etched is calculated. By subtracting the calculated time from the processing time in the etching recipe, the processing time is corrected.

Thereafter or when it is determined in step S17 that the calculated slimming amount is within the predetermined range from the reference slimming amount (YES in step S17), the substrate is fed to the etching device 110 again, and an etching process is performed again using the resist pattern 215 as a mask as illustrated in FIGS. 6G, 7G, and 8G (step S19). Here, the control device 130 controls the etching device 110 such that the etching process is performed in only the time in which the pair layer 211 corresponding to one layer exposed from the resist pattern 215 is etched in the forming area of the word line contact portion 20. Accordingly, in the word line contact portion 20, the pair layers 211-1 and 211-2 are etched and the pair layers 211-2 and 211-3 are exposed. At the forming position of the slimming amount monitoring mark 5A, the pair layer 211-2 is removed from the area between the reference pattern 51 and the measuring pattern 52 and the pair layer 211-3 is exposed. The insulating films 213 and 212 in the area in which the measuring pattern 52 is exposed are etched and a step increases in one step in comparison with the state illustrated in FIG. 8E.

Thereafter, the control device 130 determines whether the processing is completed (step S20). When the processing is not completed (NO in step S20), the process flow is returned to step S14 and the subsequent processes are repeatedly performed. When the processing is completed (YES in step S20), that is, when a level difference corresponding to the target number of steps is formed in the forming area of the word line contact portion 20, the etching process ends. The intermediate processes are not illustrated, but when the etching process ends, a stepped structure is formed in the forming area of the word line contact portion 20 as illustrated in FIG. 2.

In step S18 of FIG. 9, the processing time of the resist pattern in the etching recipe is corrected depending on the calculated slimming amount whenever the slimming amount is calculated once, but this embodiment is not limited to this example. For example, after the calculating of the slimming amount is performed plural times, the processing time of the resist pattern in the etching recipe may be corrected depending on the average calculated slimming amount thereof. The reflection in the processing time of the resist pattern in the etching recipe may be performed from a next lot.

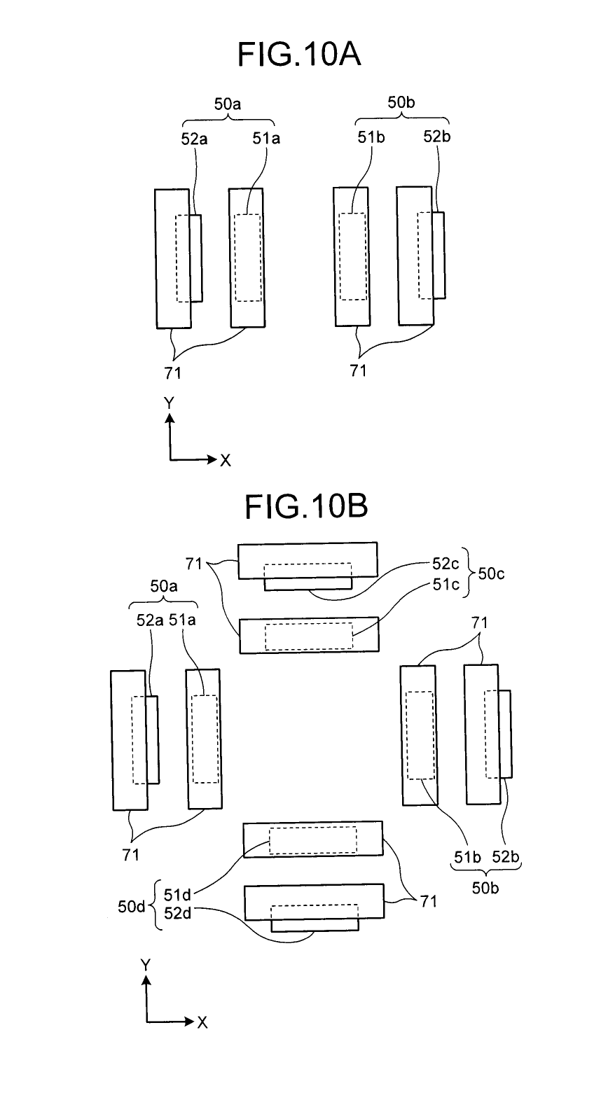

A single slimming amount monitoring mark 5A may be formed in a single mark area as illustrated in FIG. 3A or plural slimming amount monitoring marks 5A may be formed in a single mark area. FIGS. 10A and 10B are top views illustrating an example of an arrangement state of the slimming amount monitoring mark. In the drawings, the arrangement state of the resist pattern 71 under slimming is also illustrated.

FIG. 10A illustrates an example in which a pair of line patterns 50a and 50b extending in the Y axis direction is arranged in parallel. From the negative side of the X axis to the positive side, a measuring pattern 52a and a reference pattern 51a of the line pattern 50a and a reference pattern 51b and a measuring pattern 52b of the line pattern 50b are sequentially arranged. In the initial state in which the pair of line patterns 50a and 50b are formed, it is assumed that the reference patterns 51a and 51b and the measuring patterns 52a and 52b satisfy the following conditions. In a cross-section perpendicular to the extending direction of the reference patterns 51a and 51b, a difference between a midpoint between the center positions in the width of two reference patterns 51a and 51b and a midpoint in the width of two measuring patterns 52a and 52b is a predetermined value (a reference value for calculation of a variation). The reference value for calculation of a variation is preferably 0.

FIG. 11 is a diagram illustrating an example of a method of measuring the slimming amount monitoring mark illustrated in FIG. 10A. FIG. 11 illustrates a state in which a step-forming resist pattern is formed on the slimming amount monitoring mark and is slimmed.

As illustrated in FIG. 11, all of the reference patterns 51a and 51b are covered with the resist pattern 71, and only a predetermined area of the measuring patterns 52a and 52b including one long side (edge) are covered with the resist pattern 71. The midpoint between the edge of the measuring pattern 52a covered with the resist pattern 71 and the position of an end of the resist pattern 71 on the measuring pattern 52a is defined as X11, the midpoint between two edges of the reference pattern 51a is defined as X12, the midpoint between two edges of the reference pattern 51b is defined as X13, and the midpoint between the edge of the measuring pattern 52b covered with the resist pattern 71 and the position of an end of the resist pattern 71 on the measuring pattern 52b is defined as X14. The positions X11 to X14 are measured using an optical displacement inspection device, and a variation ΔS of the resist pattern 71 is calculated using Expression (4). X11X14 denotes the distance between the position X11 and the position X14, and X12X13 denotes the distance between the position X12 and the position X13.

ΔS=(X12X13/2−X11X14/2)×2 (4)

Regarding flat portions processed using the slimmed resist pattern 71, the variation ΔS of the resist pattern 71 calculated using Expression (4) and is correlated. By calculating the difference in the variation ΔS of the resist pattern 71 between neighboring flat portions, the slimming mount ΔW of the resist pattern 71 when forming the flat portions are formed is calculated.

FIG. 10B illustrates an example in which four line patterns 50a to 50d are arranged in a single mark area. That is, two line patterns 50a and 50b of which the extending direction is the Y direction and two line patterns 50c and 50d of which the extending direction is the X direction are formed. In two sets of line patterns 50a and 50b of which the extending direction is the Y direction, the arrangement of reference patterns 51a and 51b and measuring patterns 52a and 52b is the same as illustrated in FIG. 10A. In two sets of line patterns 50c and 50d of which the extending direction is the X direction, the arrangement of reference patterns 51c and 51d and measuring patterns 52c and 52d is also the same as illustrated in FIG. 10A. The method of calculating the slimming amount ΔW in each direction is the same as illustrated in FIG. 11. In this way, by preparing four sets of line patterns 50, the slimming amounts in the X direction and the Y direction can be measured.

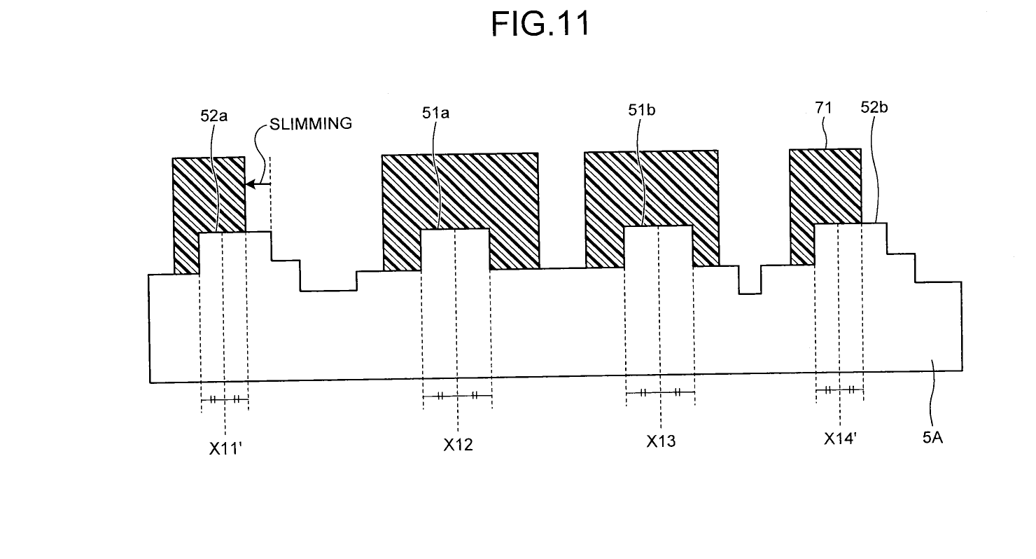

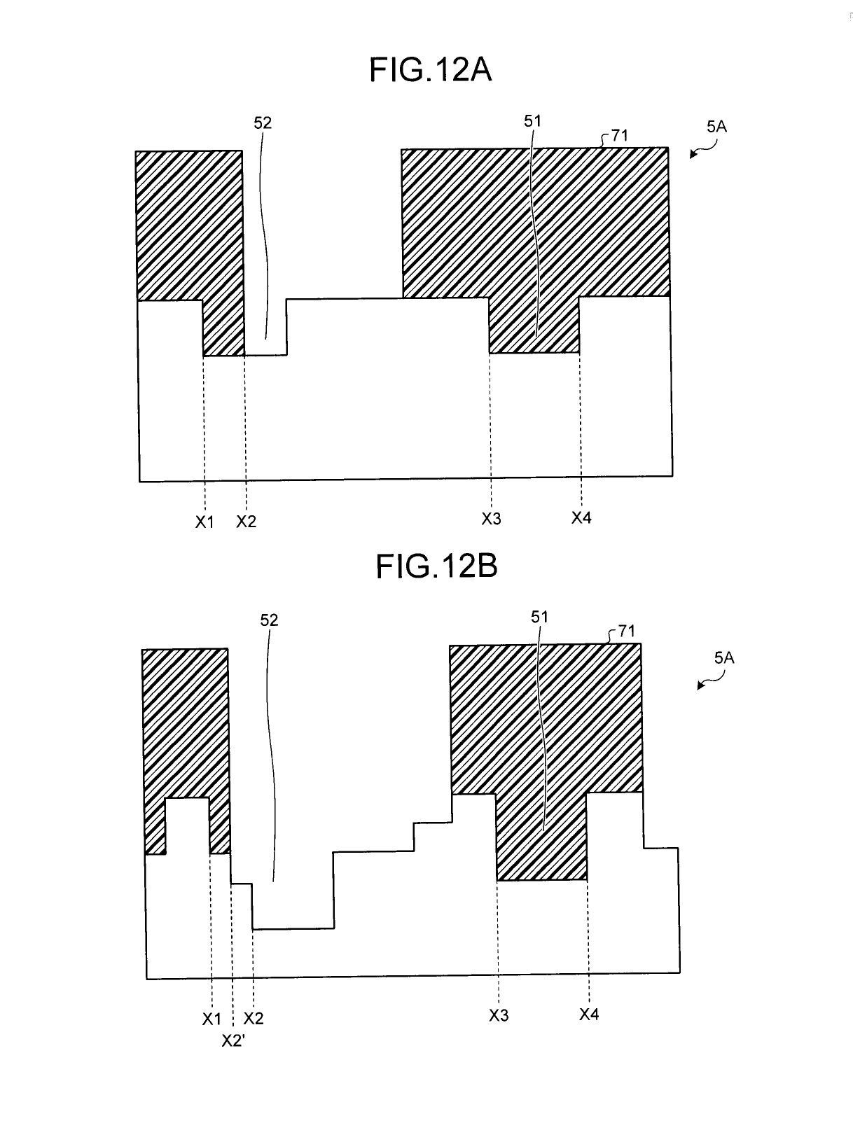

In the above-mentioned examples, the slimming amount monitoring mark 5A is constituted by the line pattern 50, but the slimming amount monitoring mark 5A may be constituted by a space pattern. FIGS. 12A and 12B are cross-sectional views schematically illustrating another example of the slimming amount monitoring mark. FIG. 12A is a cross-sectional view schematically illustrating an example of an arrangement relationship of the reference pattern 51, the measuring pattern 52, and the resist pattern 71 when the etching process is started (before the first step is formed). FIG. 12B is a cross-sectional view schematically illustrating an example of an arrangement relationship of the reference pattern 51, the measuring pattern 52, and the resist pattern 71 before the second step is formed.

This case is different from the case of the line pattern 50, in that the reference pattern 51 and the measuring pattern constituting the slimming amount monitoring mark 5A are formed as concave patterns, that is, space patterns. However, the method of monitoring the slimming amount using the reference pattern 51 and the measuring pattern 52 is the same as the case of the line pattern 50 and description thereof will not be repeated.

In the above-mentioned examples, the slimming amount is measured by the optical displacement inspection device 120 whenever a step is formed, but the slimming amount of a desired slimming process may be measured after plural steps are formed. The slimming amount is measured in a state in which a resist is formed on the slimming amount monitoring mark 5A, but the slimming amount may be measured by the optical displacement inspection device 120 after the resist is removed using a resist removing technique such as ashing.

In the first embodiment, when the resist pattern is formed on the processing target, the resist pattern is formed on the slimming amount monitoring mark 5A such that the entire reference pattern 51 is covered with the resist pattern and only one edge of the measuring pattern 52 is not covered with the resist pattern. Subsequently, the width of the resist pattern in the slimming amount monitoring mark 5A is calculated using the optical displacement inspection device 120. Thereafter, the etching process is performed using the resist pattern as a mask to slim the resist pattern. The width of the slimmed resist pattern in the slimming amount monitoring mark 5A is calculated using the optical displacement inspection device 120. The slimming amount of the resist pattern is calculated using the results and the etching time of the resist pattern in the etching recipe is corrected if necessary. Accordingly, it is possible to measure the slimming amount of the resist pattern with a simple method using the optical displacement inspection device 120. When the slimming amount departs from the reference slimming amount, the slimming time is appropriately corrected and an appropriate slimming amount can be set when the resist pattern is slimmed next time.

In the related art, a critical dimension scanning electron microscope (CD-SEM) was used to measure the slimming amount. As described above, since the length of the flat portion ranges from 500 nm to several μm, a considerably broad range should be scanned in measurement using an electron microscope. That is, the slimming amount cannot be measured by only one scanning, and the slimming amount is measured by connecting scanning results of plural times. As a result, a measurement error increases. On the contrary, in the method according to this embodiment, since the measuring range can be included in one field of view by using the optical displacement inspection device 120, it is possible to reduce the measurement error in comparison with the measurement using the CD-SEM.

### Second Embodiment

In the first embodiment, it is described that the slimming amount is measured whenever the slimming process is performed. In the second embodiment, the slimming amount is measured after the slimming process is performed plural times.

A slimming amount monitoring mark 5A for measuring a slimming amount according to the second embodiment is the same as described in the first embodiment. The configuration of the semiconductor device manufacturing apparatus for measuring the slimming amount is the same as described in the first embodiment. Now a slimming amount measuring method according to the second embodiment will be described.

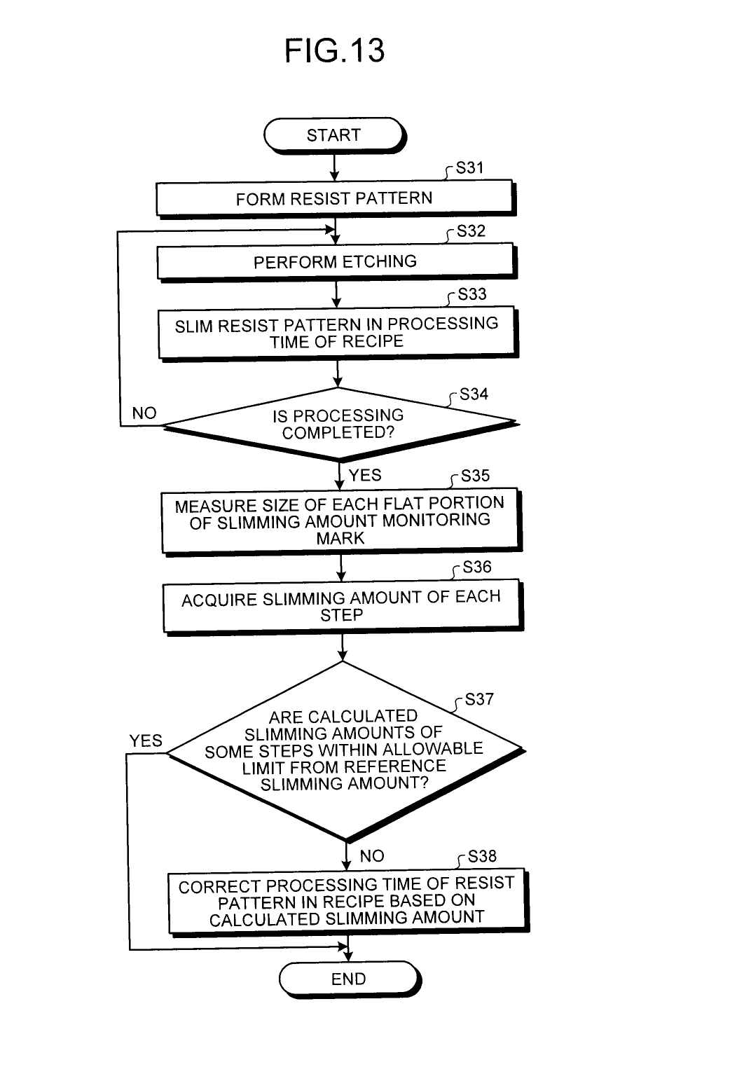

FIG. 13 is a flowchart illustrating an example of a process flow of the semiconductor device manufacturing method according to the second embodiment. The semiconductor device manufacturing method will be described below with reference to FIGS. 3A and 3B and FIGS. 6A to 8F.

First, as illustrated in FIGS. 6A to 8C of the first embodiment, plural pair layers 211 in which different types of films are stacked are stacked on a substrate not illustrated and insulating films 212 and 213 are formed thereon. Subsequently, by using a lithography technique and an etching technique, a part of the pair layer 211-1 is exposed in the forming area of the word line contact portion 20 and the slimming amount monitoring mark 5A including the reference pattern 51 and the measuring pattern 52 is formed on the scribe line.

Thereafter, as illustrated in FIGS. 6D, 7D, and 8D, a resist is applied onto the insulating film 213 the pair layer 211-1 and a resist pattern 215 having a predetermined shape is formed using a lithography technique and a developing technique (step S31). The resist pattern 215 in which the vicinity of the center of the forming area of the word line contact portion 20 is opened is formed in the forming area of the word line contact portion 20. On the scribe line, the resist pattern 215 with which the entire reference pattern 51 is covered, one edge of the measuring pattern 52 is covered, and the other edge is not covered is formed. The width of the resist pattern 215 covering the reference pattern 51 is determined so as not to expose the reference pattern 51 even when the resist pattern 215 is slimmed the number of times in which the measuring of the slimming amount is intended.

Thereafter, as illustrated in FIGS. 6E, 7E, and 8E, an etching process is performed using the resist pattern 215 as a mask so as to remove only the exposed pair layer 211-1(step S32). Subsequently, as illustrated in FIGS. 6F, 7F, and 8F, the control device 130 controls the etching device 110 so as to isotropically etch the resist pattern 215 depending on the processing time of the etching recipe (step S33).

Thereafter, the control device 130 determines whether the processing is completed (step S34). When the processing is not completed (NO in step S34), the process flow is returned to step S32 and the above-mentioned processes are repeatedly performed. For example, the processes illustrated in FIGS. 6F to 8G are performed. In this example, it is assumed that the resist pattern 215 is removed through two etching processes. When the resist pattern 215 is not removed, the measuring may be performed in a state in which the resist pattern 215 is formed or may be performed after the resist pattern 215 is removed using a resist removing technique such as ashing.

On the other hand, when the processing is completed (YES in step S34), the substrate subjected to the processing is fed to the optical displacement inspection device 120 and the size of each flat portion of the slimming amount monitoring mark 5A is measured (step S35). As illustrated in FIGS. 3A and 3B, the width of the step formed on the side of the measuring pattern 52 not covered with the resist pattern 215 almost corresponds to the slimming amount of the resist pattern 215. Accordingly, the widths b1 and b2 of the steps are measured by the optical displacement inspection device 120.

Subsequently, the control device 130 acquires the calculated slimming amount of each step from the optical displacement inspection device 120 (step S36). The steps of the slimming amount monitoring mark 5A can be correlated with the steps formed in the word line contact portion 20. Therefore, the control device 130 determines whether the calculated slimming amounts of some steps are within a predetermined range from the reference slimming amount in the etching recipe (step S37). When the calculated slimming amounts of some steps are not within the predetermined range from the slimming amount in the etching recipe (NO in step S37), the processing time of the resist pattern in the etching recipe is corrected depending on the calculated slimming amounts (step S38). This process is performed when the calculated slimming amount is not within a predetermined range from the slimming amount in the etching recipe and details thereof are the same as in step S18 of FIG. 9 according to the first embodiment. In this case, a slimming amount corrected in a subsequent process is reflected.

Thereafter or when it is determined in step S37 that the average value of the calculated slimming amounts is within a predetermined range from the slimming amount in the etching recipe (YES in step S37), the process flow ends.

In the above-mentioned example, it is determined whether the calculated slimming amount of each step is within a predetermined range from the slimming amount in the etching recipe. However, when a stepped structure is formed in the word line contact portion 20, or the like, the slimming amounts of the resist pattern 215 in the steps are generally set to the same. Accordingly, the average value of the calculated slimming amounts of the steps and correction may be performed when the correction is required by comparing the average value of the calculated slimming amounts with the slimming amount in the etching recipe.

In the second embodiment, the etching process of the pair layers 211 using the resist pattern 215 and the slimming process of the resist pattern 215 are repeatedly performed to form plural steps and then the widths of the steps of the slimming amount monitoring mark 5A are measured using the optical displacement inspection device 120. Accordingly, on the assumption that the slimming amounts of the steps are almost equal to the widths of the steps, it is possible to collectively measure the slimming amounts of the steps. In addition to the effects of the first embodiment, it is possible to shorten the time required for calculating the slimming amount in comparison with the first embodiment.

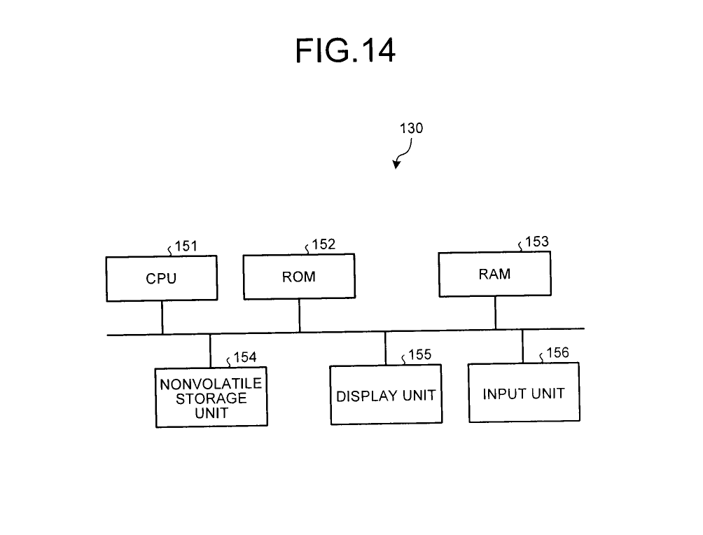

Now, the hardware configuration of the control device 130 will be described. FIG. 14 is a diagram illustrating an example of a hardware configuration of the control device. The control device 130 is a computer including a central processing unit (CPU) 151, a read only memory (ROM) 152, a random access memory (RAM) 153, a nonvolatile memory unit 154, a display unit 155, and an input device 156. In the control device 130, the CPU 151, the ROM152, the RAM 153, the nonvolatile memory unit 154, the display unit 155, and the input device 156 are connected via a bus line.

The etching method based on the etching recipe and the method of correcting the etching recipe are provided as a program. This program is recorded on a computer-readable recording medium such as a CD-ROM, a flexible disk (FD), a CD-R, a digital versatile disk (DVD), and a memory card in a file of an installable format or an executable format and is provided.

In addition, the methods may be provided by storing a program according to this embodiment, which is executed by a contents distribution system, in a computer connected to a network such as Internet and downloading the program via the network. In addition, a program according to this embodiment, which is executed by a contents distribution system, may be provided or distributed via a network such as Internet.

The program has a module configuration including the above-mentioned units (the etching control unit 131, the slimming amount calculating unit 133, and the etching correcting unit 134). As actual hardware, by causing the CPU 151 (processor) to read the program from the storage medium and to execute the read program, the units are loaded onto a main memory device and the etching control unit 131, the slimming amount calculating unit 133, and the etching correcting unit 134 are generated on the main memory device.

The program may be configured to be installed in the ROM 152 or the like and to be provided.

While it is described above that the slimming amount monitoring mark 5A is disposed on the scribe line, the embodiment is not limited to this example. For example, the slimming amount monitoring mark 5A may be disposed in an area in which no element is formed on a chip area.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising a mark, the mark including:
a reference pattern extending in a first direction;
a measuring pattern extending in the first direction;
a first stepped portion disposed on one side in a second direction intersecting the first direction of the measuring pattern,
wherein the measuring pattern is separated by a predetermined distance in the second direction from the reference pattern, and
the first stepped portion has a level difference of one or more steps.

2. The semiconductor device according to claim 1, wherein the mark is disposed in an area in which no element is formed or on a scribe line.

3. The semiconductor device according to claim 1, wherein the level difference of the first stepped portion is correlated with a part of a level difference of a second stepped portion formed in an element.

4. The semiconductor device according to claim 3, wherein the mark is disposed such that a step-forming direction of the second stepped portion is the second direction.

5. The semiconductor device according to claim 3, wherein the element has the second stepped portion in which a plurality of pair layers are stacked and the pair layers are arranged in a step shape, each pair layer including an electrode film and an insulating film.

6. The semiconductor device according to claim 1, wherein the size in the second direction of the reference pattern is greater than the size in the second direction of the measuring pattern.

7. The semiconductor device according to claim 1, wherein the reference pattern and the measuring pattern are line patterns or space patterns.

8. The semiconductor device according to claim 1, wherein two or more marks are disposed in a single mark area.

9. The semiconductor device according to claim 1, wherein two marks are arranged in parallel with each other in a single mark area.

10. The semiconductor device according to claim 1, wherein four marks are disposed in a single mark area, and
the four marks include two first marks having the same extending direction and two second marks having an extending direction perpendicular to the first marks.

11. A method of manufacturing a semiconductor device, comprising:
forming a mark including a reference pattern and a measuring pattern in a mark-forming area of a processing target, the reference pattern and the measuring pattern extending in a first direction, the reference pattern and the measuring pattern being separated by a predetermined distance in a second direction intersecting the first direction from each other;
forming a resist pattern so as to cover a predetermined area in an element-forming area of the processing target, to cover all the reference pattern, and to cover the measuring pattern to expose one edge in the second direction,
measuring first position measurement information including positions of predetermined portions of the reference pattern, the measuring pattern, and the resist pattern in the second direction in the mark-forming area;
etching the processing target using the resist pattern as a mask;
slimming the resist pattern through isotropic etching in a reference time defined in a recipe;
measuring second position measurement information including positions of predetermined portions of the reference pattern, the measuring pattern, and the resist pattern in the second direction in the mark-forming area;
calculating a calculated slimming amount of the resist pattern using the first position measurement information and the second position measurement information;
determining whether the calculated slimming amount is within a predetermined range from a reference slimming amount acquired from the recipe; and
correcting the reference time based on a period of time corresponding to a difference between the calculated slimming amount and the reference slimming amount when the calculated slimming amount is not within the predetermined range from the reference slimming amount.

12. The method of manufacturing a semiconductor device according to claim 11, wherein the measuring of the first position measurement information and the second position measurement information is performed using an optical inspection device.

13. The method of manufacturing a semiconductor device according to claim 11, wherein,
in the measuring of the first position measurement information, a position of an end of the reference pattern in the second direction, a position of an end of the measuring pattern covered with the resist pattern, and a position of an end of the resist pattern on the measuring pattern are measured,
in the measuring of the second position measurement information, a position of an end of the reference pattern in the second direction, a position of an end of the measuring pattern covered with the resist pattern, and a position of an end of the slimmed resist pattern on the measuring pattern are measured.

14. The method of manufacturing a semiconductor device according to claim 13, wherein, in the calculating of the calculated slimming amount, a difference between a width of the resist pattern calculated based on the first position measurement information and a width of the slimmed resist pattern calculated based on the second position measurement information is calculated.

15. The method of manufacturing a semiconductor device according to claim 13, wherein, in the calculating of the calculated slimming amount, the calculated slimming amount is calculated using a first inter-center distance between the reference pattern and the measuring pattern which is calculated based on the first position measurement information and a second inter-center distance between the reference pattern and the measuring pattern which is calculated based on the second position measurement information.

16. The method of manufacturing a semiconductor device according to claim 11, wherein the etching of the processing target to the measuring of the second position measurement information are repeatedly performed after the measuring of the second position measurement information, and
in the calculating of the calculated slimming amount, the calculated slimming amount is calculated based on the second position measurement information and the second position measurement information measured after the slimming.

17. A method of manufacturing a semiconductor device, comprising:
forming a mark including a reference pattern and a measuring pattern in a mark-forming area of a processing target, the reference pattern and the measuring pattern extending in a first direction, the reference pattern and the measuring pattern being separated by a predetermined distance in a second direction intersecting the first direction from each other;
forming a resist pattern so as to cover a predetermined area in an element-forming area of the processing target, to cover all the reference pattern, and to cover the measuring pattern to expose one edge in the second direction,
etching the processing target using the resist pattern as a mask;
slimming the resist pattern through isotropic etching in a reference time defined in a recipe;
etching the processing target using the slimmed resist pattern as a mask;
measuring sizes of flat portions of a stepped structure which is formed on a side of the measuring pattern not covered with the resist pattern after the etching, the sizes of the flat portions being sizes in the step-forming direction;
setting the sizes of the flat portions as the calculated slimming amount;
determining whether the calculated slimming amount is within a predetermined range from a reference slimming amount acquired from the recipe; and
correcting the reference time based on a period of time corresponding to a difference between the calculated slimming amount and the reference slimming amount when the calculated slimming amount is not within the predetermined range from the reference slimming amount.

18. The method of manufacturing a semiconductor device according to claim 17, wherein the measuring of the sizes of the flat portions is performed using an optical inspection device.

19. The method of manufacturing a semiconductor device according to claim 17, wherein the average of the sizes of the flat portions is set as the calculated slimming amount in the setting of the calculated slimming amount.

20. The method of manufacturing a semiconductor device according to claim 17, wherein the slimming to the etching of the processing target are repeatedly performed a predetermined number of times after the etching of the processing target and before the measuring of the sizes of the flat portions.
